(19) United States
(12) Patent Application Publication
(10) Pub. No.: US 2026/0217009 A1
(43) Pub. Date: Jul. 30, 2026

(54) GANTRY TYPE STAGE

(71) Applicant: VIATRON TECHNOLOGIES, INC., Gyeonggi-do (KR)

(72) Inventors: Hyoung June Kim, Seoul (KR); Byung Kuk Kim, Gyeonggi-do (KR); Min Su Back, Gyeonggi-do (KR); Kyu Won Lee, Gyeonggi-do (KR); Gyoung Nam Kim, Gyeonggi-do (KR); Kang Sik Nam, Gyeonggi-do (KR)

(21) Appl. No.: 19/141,285

(22) PCT Filed: Dec. 22, 2023
(86) PCT No.: PCT/KR2023/021460

§ 371 Date: Jun. 19, 2025

(30) Foreign Application Priority Data
Dec. 28, 2022 (KR) 10-2022-0186840

(51) Int. Cl. B32B 37/00; H10P 72/00

(52) U.S. Cl. CPC B32B 37/0046; B32B 37/025; H10P 72/0616; B32B 2457/14

(57) ABSTRACT

The present disclosure discloses a gantry-type stage including a base frame having a base space formed on an inner upper side thereof; two first transfer modules, each of which comprising a first transfer block configured to be moved in a first direction, and being coupled to one side and the other side of the base frame, respectively; a second transfer module comprising a second transfer block configured to be moved in a second direction perpendicular to the first direction; third transfer modules, each of which comprising a third transfer block configured to be moved in a third direction perpendicular to the first and second directions; and a mounting module comprising a mounting block placed between the third transfer modules at a front side of the second transfer block and a mounting hinge coupled between both sides of the mounting block and the third transfer module.

### TECHNICAL FIELD

The present disclosure relates to a stage formed in a gantry-type to transfer a camera module.

### BACKGROUND ART

A gantry-type stage may be used to transfer an object, which is to be transferred, in three axial (X-axial, Y-axial and Z-axial) directions in a semiconductor device manufacturing apparatus, or the like. For example, the gantry-type stage may be used to inspect or check a condition or a bonding status of a semiconductor device while transferring a camera module in the process of bonding the semiconductor device. The gantry-type stage should be transferred to prevent the camera module from being out of focus, allowing the camera module to take precise shots. The gantry-type stage should be transferred such that the camera module is not out of focus, allowing the camera module to take precise shots. However, during the process of transferring the camera module, the gantry-type stage may cause vibration to the camera module due to inertia, vibration of a he frame, or the like. In other words, the gantry-type stage has a problem that, due to yawing and pitching, errors are caused in the camera module and the camera module is out of focus and the precision of the captured image is thus reduced. In particular, the camera module is more prone to the problem that the precision of the captured image is degraded by the pitching error.

### DISCLOSURE OF THE INVENTION

### Technical Problem

An object of the present disclosure is to provide the gantry-type stage which compensates for a pitching error to improve a linear transferring precision.

### Technical Solution

A gantry-type stage of the present disclosure includes a base frame having a base space formed on an inner upper side thereof; two first transfer modules, each of which comprising a first transfer block configured to be moved in a first direction, and being coupled to one side and the other side of the base frame, respectively; a second transfer module comprising a second transfer block configured to be moved in a second direction perpendicular to the first direction, the second transfer module being coupled to the first transfer block between the first transfer modules to be moved in the first direction; third transfer modules, each of which comprising a third transfer block configured to be moved in a third direction perpendicular to the first and second directions, the second transfer modules being coupled to one side and the other side of the second transfer block, respectively, at a front surface of the second transfer block to be moved in the second direction; and a mounting module comprising a mounting block placed between the third transfer modules at a front side of the second transfer block and a mounting hinge coupled between both sides of the mounting block and the third transfer module.

In addition, the third transfer modules comprise a third left transfer module and a third right transfer module, the mounting block is placed between the third left transfer module and the third right transfer module, and the mounting hinge may include a left mounting hinge placed between a left side of the mounting block and the third transfer block of the third left transfer module, and a right mounting hinge placed between a right side of the mounting block and the third transfer block of the third right transfer module.

Also, the mounting hinge is formed in the shape of a bar, and may have a plurality of hinge holes passing therethrough from one side to the other side thereof in a direction perpendicular to height and width directions.

Further, the hinges holes may be formed to be spaced apart from each other in a longitudinal direction of the mounting hinge.

In addition, the left mounting hinge and the right mounting hinge may be formed to have the same length and have the same number of hinges holes.

Alternatively, the left mounting hinge and the right mounting hinge may be formed to have the same length and have the different number of hinges holes.

Also, the mounting hinge may be formed from an aluminum material.

Further, the mounting hinge may be coupled to one side, the other side and a portion facing the third transfer block of the mounting block.

In addition, the mounting hinge may be formed to have a height corresponding to a relatively short height out of a height of the mounting block and a height of the third transfer block.

### Advantageous Effects

The gantry-type stage of the present disclosure may compensate for a pitching error to improve a linear transferring precision.

In addition, the gantry-type stage of the present disclosure may compensate for a pitching error to improve the precision for a captured image of the camera module.

### BRIEF DESCRIPTION OF THE DRAWINGS

FIG. 1 is a perspective view of a gantry-type stage according to one embodiment of the present disclosure.

FIG. 2 is a partial plane view of a part including a third transfer module and a mounting module of FIG. 1.

FIG. 3 is a partial top view of a part including the third transfer module and the mounting module of FIG. 2.

FIG. 4 is a front view of a mounting hinge of the mounting module of FIG. 1.

FIG. 5 is a vertical cross-sectional view of the mounting hinge of FIG. 4.

FIG. 6 is a partially enlarged view of the mounting module of FIG. 1.

FIG. 7 is a front view showing a state in which a camera module is mounted on the mounting module of FIG. 1.

FIG. 8 is a plane view of FIG. 7.

### BEST MODE FOR CARRYING OUT THE INVENTION

Hereinafter, a gantry-type stage of the present disclosure is described in more detail with reference to embodiments and the accompanying drawings.

First, a gantry-type stage according to one embodiment of the present disclosure is described.

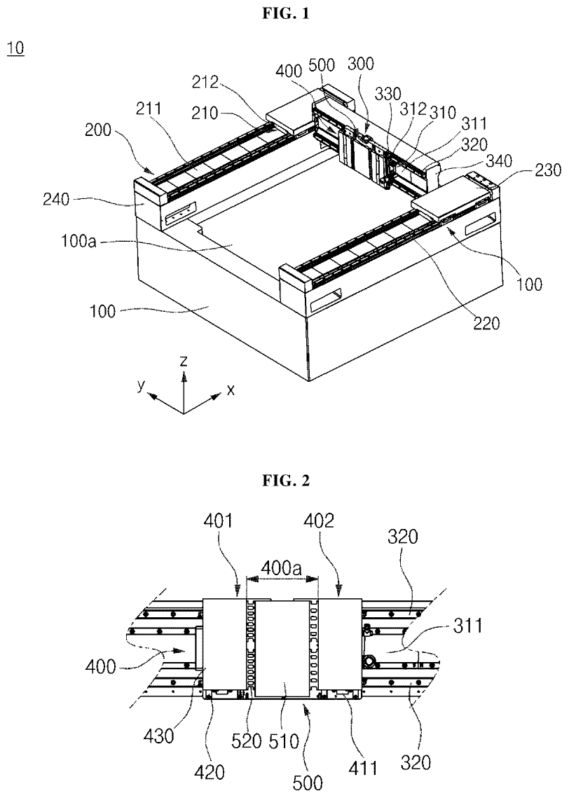

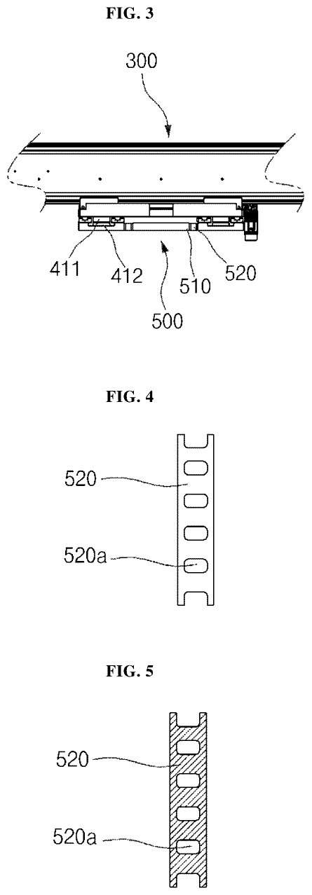

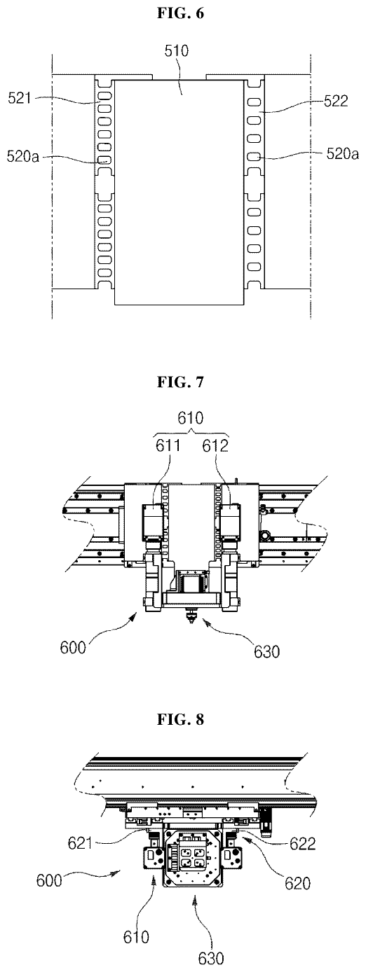

FIG. 1 is a perspective view of a gantry-type stage according to one embodiment of the present disclosure. FIG. 2 is a partial front view of a part including a third transfer module and a mounting module of FIG. 1. FIG. 3 is a partial plane view of a part including the third transfer module and the mounting module of FIG. 2. FIG. 4 is a front view of a mounting hinge of the mounting module of FIG. 1. FIG. 5 is a vertical cross-sectional view of the mounting hinge of FIG. 4. FIG. 6 is a partially enlarged view of the mounting module of FIG. 1.

Referring now to FIGS. 1 to 6, a gantry-type stage 10 according to one embodiment of the present disclosure may include a base frame 100, a first transfer module 200, a second transfer module 300, a third transfer module 400 and a mounting module 500.

The gantry-type stage 10 can transfer a mounting block in a first direction, a second direction, and a third direction. In particular, the gantry-type stage 10 may transfer a mounting module 500 in the third direction while transferring the third transfer module 400 in the second direction. At this time, the gantry-type stage 10 may cause a left side and a right side of the mounting module 500 to be transfer in opposite up and down directions.

Hereinafter, the first direction refers to a x direction in FIG. 1, the second direction refers to the y direction, and the third direction refers to a z direction. In addition, a front side and a rear side refer to the first direction, a left side and a right side, and one side and the other side refers to the second direction, and an upper side and a lower side refer to the third direction.

The base frame 100 may be formed in the shape of a hexagonal block or a square plate. Furthermore, the base frame 100 may be formed in the shape of a hexahedron by pipes or tubes. The transfer modules 200 may be mounted on one side and the other side of an upper surface of the base frame 100, respectively. In addition, the base frame 100 may have a base space 100a formed in an inner side thereof and extended downward by a predetermined depth from the upper surface thereof. The first transfer modules 200 may be mounted on one side and the other side with respect to the base space 100a, respectively. The base space 100a may provide a space in which a semiconductor device is accommodated. Furthermore, the base space 100a may provide a space in which a lower portion of a transfer object, such as a camera mounted on the mounting module 500, is accommodated.

The first transfer module 200 may include a first transfer means 210, a first transfer rail 220, and a first transfer block 230. In addition, the first transfer module 200 may further include a first support block 240. The first transfer module 200 may be formed such that the first transfer block 230 is moved in the first direction by the first transfer means 210 and the first transfer rail 220. The two first transfer modules 200 may mounted on one side and the other side of the base frame 100 such that they are extended in the first direction while being spaced apart from each other in the second direction.

The first transfer means 210 may be formed by a linear motor. The first transfer means 210 may include a first transfer magnet 211 arranged in the first direction and a first transfer coil 212 placed above the first transfer magnet 211. That is, the first transfer magnet 211 may be coupled to the upper surface of the base frame 100 and the first transfer coil 212 may be placed to be spaced apart from the first transfer magnet 211 in an upward direction. The first transfer coil 212 may be coupled and secured to a lower surface of the first transfer block 230. In addition, as the first transfer means 210, various means for transferring the first transfer block 230 in the first direction may be employed. For example, the first transfer means 210 may be composed of a ball screw and a servo motor. The two first transfer means 210 may be mounted on one side and the other side of the base frame 100 such that they are extended in the first direction while being spaced apart from each other in the second direction.

The first transfer rails 220 may be mounted on one side and the other side of the first transfer means 210, respectively, such that they are extended in the first direction. A linear-motion (LM) rail of a linear-motion (LM) guide may be employed as the first transfer rail 220.

The first transfer block 230 may be formed in the shape of a block and coupled to the first transfer rail 220. A LM block of a LM guide may be employed as the first transfer block 230. The first transfer block 230 may be coupled to the first transfer rail 220 via first block grooves (not shown) formed on lower surfaces of one side and the other side thereof. In addition, the first transfer coil 212 of the first transfer means 210 is coupled to a lower surface of an intermediate portion of the first transfer rail 220. The first transfer block 230 is moved along the first transfer rail 220 by operation of the first transfer means 210.

The first support block 240 may be formed in the shape of a block having a predetermined width and length. The first support block 240 may be formed to have an area and shape necessary for seating the first transfer means 210 and the first transfer rail 220 on an upper surface thereof. On an upper side of the base frame 100, the first support block 240 may be placed below the first transfer means 210 and the first transfer rail 220. The first support block 240 may be coupled to one side and the other side of the base frame 100, respectively, to support the first transfer means 210 and the first transfer rail 220 on an upper surface thereof.

The second transfer module 300 may include a second transfer means 310, second transfer rails 320, and a second transfer block 330. In addition, the second transfer module 300 may further include a second support block 340. The second transfer module 300 may be formed such that the second transfer block 330 is moved along the second direction by the second transfer means 310 and the second transfer rail 320. In addition, one side and the other side of the second transfer module 300 may be coupled to the first transfer modules 200 placed on one side and the other side of the base frame 100. In other words, the second transfer module 300 may be coupled to the first transfer module 200 such that it is extended in a direction orthogonal to the first transfer module 200. There, the second transfer module 300 may be transferred entirely in the first direction by the first transfer module 200.

The second transfer means 310 may be formed by the means which is the same as that employed as the first transfer means 210. For example, a linear motor may be employed as the second transfer means 310. The second transfer means 310 may include a second transfer magnet 311 arranged in the second direction and a second transfer coil 312 placed at the front of the second transfer magnet 311. That is, the second transfer magnet 311 may be coupled to a front surface of the first transfer block 230, and the second transfer coil 312 may be placed to be spaced apart from the second transfer magnet 311 in a forward direction. The second transfer coil 312 may be coupled to and secured to a rear surface of the second transfer block 330. In addition, as the second transfer means 310, various means for transferring the second transfer block 330 in the second direction may be employed. For example, the second transfer means 310 may be composed of a ball screw and a servo motor. One side and the other side of the second transfer mean 310 may be mounted on the first transfer blocks 230 of the first transfer modules 200 placed at one side and the other side of the base frame 100. In other words, the second transfer means 310 may be coupled to the first transfer blocks 230 such that it is extended in a direction orthogonal to the first transfer means 210.

The second transfer rails 320 may be mounted on upper and lower sides of the second transfer means 310, respectively, such that they are extended in the second direction. A LM rail of a LM guide may be employed as the second transfer rail 320.

The second transfer block 330 is formed in the shape of a block, and may be coupled to the second transfer rail 320. A LM block of a LM guide may be employed as the second transfer block 330. The second transfer block 330 may be coupled to the second transfer rails 320 via second block grooves (not shown), which are formed on an upper rear surface and a lower rear surface of the second transfer block to be extended in the second direction. In addition, the second transfer coil 312 of the second transfer means 310 may be coupled to a rear side of an intermediate portion of the second transfer block 330. The second transfer block 330 may be moved in the first direction along the second transfer rail 320 by operation of the second transfer means 310.

The second support block 340 may be formed in the shape of a block having a predetermined width and length. The second support block 340 may be formed to have an area and shape necessary for seating the second transfer means 310 and the second transfer rail 320 on a front surface thereof. The second support block 340 may be placed at rear sides of the second transfer means 310 and the second transfer rail 320 between the first transfer modules 200 placed at one side and the other side of the base 100. The second support block 340 may be coupled between the first transfer modules 200 while supporting the second transfer means 310 and the second transfer rail 320 via the front surface thereof.

The third transfer module 400 may include a third transfer means 410, a third transfer rail 420, and a third transfer block 430. The third transfer module 400 may be formed such that the third transfer block 430 is moved in the third direction by the third transfer means 410 and the third transfer rail 420. The two third transfer blocks 430 may be provided. That is, the third transfer module 400 may be composed of a third left transfer module 401 and a third right transfer module 402. The third left transfer module 401 and the third right transfer module 402 may be formed to the same configuration. However, in the process of correcting the pitching, movement directions of the third transfer blocks 430 of the third left transfer module 401 and the third right transfer module 402 may differ from each other, for example, in an upward direction or a downward direction. In the third transfer module 400, furthermore, the third left transfer module 401 and the third right transfer module 402 are spaced apart by a third separation distance 400a in the second direction at a front surface of the second transfer block 330 to allow these modules to be coupled to one side and the other side. In addition, the third transfer module 400 may be coupled to the second transfer block 330 of the second transfer module 300 such that it is extended in a direction orthogonal to the second transfer module 300. Therefore, the third transfer module 400 may be transferred in the second direction as a whole by the second transfer module 300.

The third transfer means 410 may be formed by the same means as the first transfer means 210. For example, a linear motor may be employed as the third transfer means 410. The third transfer means 410 may include a third transfer magnet 411 arranged in the third direction and a third transfer coil 412 placed at a front side of the third transfer magnet 411. That is, the third transfer magnet 411 may be coupled to a front surface of the second transfer block 330 and the third transfer coil 412 may be placed while being spaced apart from a front side of the third transfer magnet 411. The third transfer coil 412 may be coupled to and secured to a rear surface of the third transfer block 430.

In addition, as the third transfer means 410, various means for transferring the third transfer block 430 in the third direction may be employed. For example, the third transfer means 410 may be composed of a ball screw and a servo motor. An upper side and a lower side of the third transfer means 410 may be coupled to a front surface of the second transfer block 330 of the second transfer module 300. In other words, the third transfer means 410 may be coupled to the second transfer block 330 such that it is extended in a direction orthogonal to the second transfer means 310. The third transfer means 410 may be formed to have a length equal to or less than a height of the second transfer block 330.

The third transfer rails 420 may be mounted on one side and the other side of the third transfer means 410 to be extended in the third direction, respectively. A LM rail of a LM guide may be employed as the second transfer rail 420.

The third transfer block 430 is formed in the shape of a block, and may be coupled to the third transfer rail 420. A LM block of a LM guide may be employed as the third transfer block 430. The third transfer block 330 may be coupled to the third transfer rail 420 via third block grooves (not shown), which are formed on a left rear surface and a right rear surface of the third transfer block to be extended in the third direction. Further, the third transfer coil 412 of the third transfer means 410 may be coupled to a rear surface of an intermediate portion of the third transfer block 430. The third transfer block 430 may be moved in the third direction along the third transfer rail 420 by operation of the third transfer means 410.

The mounting module 500 may include a mounting block 510 and a mounting hinge 520. At a front side of the second module 300, the mounting module 500 may be coupled between the third transfer modules 400. More specifically, the mounting module 500 may be coupled between the third transfer blocks 430 of the third left transfer module 401 and the third right transfer module 402. The mounting module 500 may be moved in the third direction by the third transfer means 410. Further, the third left transfer module 401 and the third right transfer module 402 may be moved in different directions, or only one of them may be moved to allow one side or the other of the mounting module 500 to be moved in the opposite third direction. The mounting module 500 may be such that its height is fixed after the third transfer block 430 is moved in the third direction. Thus, the mounting module 500 may be such that it allows its relative height to be maintained after either of the third transfer blocks 430 coupled to the mounting hinge 520 is resiliently moved.

The mounting block 510 may be formed as a roughly square shaped block. The mounting block 510 may be formed to have a suitable area depending on a distance between the third transfer block 430 and the mounting block. The mounting block 510 may be placed between the third left transfer module 401 and the third right transfer module 402. The mounting block 510 may be parallel to and placed to be spaced apart from the second transfer block 330 in a forward direction.

The mounting hinge 520 may be formed in the shape of a bar and may be formed to have a length smaller than a length of the mounting block 510. The mounting hinge 520 may be formed to have a height corresponding to a relatively short height out of a height of the mounting block 510 and a height of the third transfer block 430. Further, the plurality of mounting hinges 520 may be employed, and placed at each of left and right sides of the mounting block 510. The plurality of segmented mounting hinges 520 may be formed such that they have an entire length equal to or less than a height of the mounting block 510. For example, the mounting hinges 520 may be formed such that two separated mounting hinges are placed on each of a left side and a right side of the mounting block 510, as shown in FIG. 6. The mounting hinge 520 may be formed to have elasticity in a height direction. Here, the height direction may refer to the third direction. The mounting hinge 520 may have a hinge hole 520a passing therethrough from one side to the other side thereof in a direction perpendicular to the length and width directions. The plurality of hinge holes 520a may be formed to be spaced apart from each other in the height direction. The mounting hinge 520 may be formed from an aluminum material.

The mounting hinge 520 may be composed of a left mounting hinge 521 and a right mounting hinge 522.

The mounting hinge 520 may have elasticity which is adjustable depending on the number of hinge holes 520a formed along its entire length. As the number of hinge holes 520a having the same size is increased, a spacing between the hinge holes 520a may be decreased, and elasticity or a degree of deformation of the mounting hinge 520 may be increased. In other words, a force required for deforming the mounting force 520 may be reduced.

The left mounting hinge 521 and the right mounting hinge 522 may be formed to have the same length, and the number of and a separation distance between the hinge holes 520 formed in the left mounting hinge 521 may be the same as them of the hinge holes formed in the right mounting hinge 522. Thus, the left mounting hinge 521 and the right mounting hinge 522 have the same vertical cross-sectional area, and a force required to deform the left mounting hinge may be the same as that required to deform the right mounting hinge. Here, the above vertical cross-sectional area refers to an area of the cross-section exposed when the mounting hinge 520 is cut in the third direction and a central axial direction of the hinge hole 520a.

Further, as shown in FIG. 6, the left mounting hinge 521 and the right mounting hinge 522 may differ from each other. That is, the left mounting hinge 521 may have a greater number of hinge holes 520a compared to the right mounting hinge 522. The left mounting hinge 521 may be formed to have a relatively small vertical cross-sectional area. Accordingly, less force may be required for deforming the left mounting hinge 521 in the third direction.

The following describes operation on the gantry-type stage according to one embodiment of the present disclosure.

FIG. 7 is a front view showing a state in which a camera module is mounted on the mounting module of FIG. 1. FIG. 8 is a plane view of FIG. 7.

As shown in FIGS. 7 and 8, in the gantry-type stage 10, a camera module 600 may be mounted on the mounting module 500 to inspect a condition or a bonding status of the semiconductor device in a bonding process for the semiconductor device.

The camera module 600 may include two cameras 610 and a camera securing block 620. That is, the cameras 610 may include a left camera 611 and a right camera 612. Further, like the cameras 610, the camera securing block 620 is composed of two camera securing blocks, and may include a left camera securing block 621 and a right camera securing block 622. In addition, the camera module 600 may include an additional structure 630 required for operation of the two cameras 610.

A camera having various specifications used in a semiconductor device manufacturing apparatus may be employed as the camera 610. During a bonding process for the semiconductor device, the camera 610 may photograph a condition or a bonding status of the semiconductor device.

The left camera 611 is coupled to the third left transfer module 401 together with the left camera securing block 621, and the right camera 612 is coupled to the third right transfer module 402 together with the right camera securing block 622. The left camera 611 together with the third left transfer module 401, and the right camera 612 together with the third right transfer module 402 may be moved in the same direction along the third direction. Further, the left camera 611 and the right camera 612 may be moved in opposite directions along the third direction.

A semiconductor device may be seated in the base space 100a of the base frame 100. As the first transfer block 230 is moved in the first direction, the first transfer module 200 may move the second transfer module 300 in the first direction. As the second transfer block 330 is moved in the second direction, the second transfer module 300 may move the third transfer module 400 in the second direction.

As the third transfer block 430 is moved in the third direction, the third transfer module 400 may move the camera module 600 in the third direction. Further, the third left transfer module 401 and the third right transfer module 402 of the third transfer module 400 may be moved independently to move the left camera 611 and the right camera 612, respectively, in the third direction.

When the left camera 611 and the right camera 612 are coupled to the third transfer block 430 of the third left transfer module 401 and the third transfer block 430 of the third right transfer module 402, respectively, they may be in different positions relative to the third direction. That is, the left camera 611 and the right camera 612 may differ from each other in height. Therefore, it is necessary to adjust a height of one of the left camera 611 and the right camera 612 relative to the other. At this time, it is possible to move the camera 610 of the third transfer module 400 connected to the left mounting hinge 521 which has a relatively high elasticity, among the mounting hinge 520 to which the third left transfer module 401 and the third right transfer module 402 are connected. As shown in FIG. 6, since the left mounting hinge 521 placed on the left side of the mounting block 510 has higher elasticity, the left camera 611 may be moved relatively. In other words, a height of the left camera 611 may be adjusted relative to the right camera 612. The third left transfer module 401 may operate the third transfer means 410 to move the left camera 611 while moving the third transfer block 430 in the third direction. Thus, the third transfer block 430 may be moved in the third direction together with the left camera 611 to change a height thereof. Further, since the third transfer block 430 is in a state of being coupled with the mounting hinge 520, it is fixed at the changed height and may not be changed during a transfer of the third transfer module 400. The mounting hinge 520 is elastically deformed to allow the third transfer block 430 to be moved in the third direction. Thus, the left camera 611 may also be fixed at the changed height together with the third transfer block 430.

Further, the third transfer module 400 may be moved in the third direction while being controlled according to a pitching error measured by a pitch sensor mounted on the gantry-type stage 10. The pitch sensor may be mounted on the second transfer block 330 or the third transfer block 430. The pitch sensor may be installed on each of the third transfer block 430 of the third left transfer module 401 and the third transfer block 430 of the third right transfer module 402. The pitch sensor may measure the pitch error generated when the second transfer block 330 is being transferred in the second direction. The third transfer module 400 may reflect the pitching error generated during the movement process, to move each of the left camera 611 and the right camera 612 in the third direction.

In order to help those skilled in the art to understand, the embodiments disclosed herein are the most preferred embodiments selected from the various implementable embodiments, and are set forth in the present specification. In addition, the technical spirit of the present disclosure is not necessarily restricted or limited only by these embodiments, and various changes, additions, and modification are possible without departing from the technical spirit of the present disclosure, and implementations of other equivalent embodiments are possible.

1. A gantry-type stage, comprising:
a base frame having a base space formed on an inner upper side thereof;
two first transfer modules, each of which comprising a first transfer block configured to be moved in a first direction, and being coupled to one side and the other side of the base frame, respectively;
a second transfer module comprising a second transfer block configured to be moved in a second direction perpendicular to the first direction, the second transfer module being coupled to the first transfer block between the first transfer modules to be moved in the first direction;
third transfer modules, each of which comprising a third transfer block configured to be moved in a third direction perpendicular to the first and second directions, the second transfer modules being coupled to one side and the other side of the second transfer block, respectively, at a front surface of the second transfer block to be moved in the second direction; and
a mounting module comprising a mounting block placed between the third transfer modules at a front side of the second transfer block and a mounting hinge coupled between both sides of the mounting block and the third transfer module.

2. The gantry-type stage of claim 1,
wherein the third transfer modules comprise a third left transfer module and a third right transfer module,
wherein the mounting block is placed between the third left transfer module and the third right transfer module,
wherein the mounting hinge comprises a left mounting hinge placed between a left side of the mounting block and the third transfer block of the third left transfer module, and a right mounting hinge placed between a right side of the mounting block and the third transfer block of the third right transfer module.

3. The gantry-type stage of claim 2, wherein the mounting hinge is formed in the shape of a bar, and has a plurality of hinge holes passing therethrough from one side to the other side thereof in a direction perpendicular to height and width directions.

4. The gantry-type stage of claim 3, wherein the hinges holes are formed to be spaced apart from each other in a longitudinal direction of the mounting hinge.

5. The gantry-type stage of claim 3, wherein the left mounting hinge and the right mounting hinge are formed to have the same length and have the same number of hinges holes.

6. The gantry-type stage of claim 3, wherein the left mounting hinge and the right mounting hinge are formed to have the same length and have the different number of hinges holes.

7. The gantry-type stage of claim 1, wherein the mounting hinge is formed from an aluminum material.

8. The gantry-type stage of claim 1, wherein the mounting hinge is coupled to one side, the other side and a portion facing the third transfer block of the mounting block.

9. The gantry-type stage of claim 1, wherein the mounting hinge is formed to have a height corresponding to a relatively short height out of a height of the mounting block and a height of the third transfer block.
